(19) United States
(12) Patent Application Publication
(10) Pub. No.: US 2024/0290790 A1
(43) Pub. Date: Aug. 29, 2024

(54) SEMICONDUCTOR DEVICE AND METHOD OF FABRICATING THE SAME

(71) Applicant: Samsung Electronics Co., Ltd., Suwon-si (KR)

(72) Inventor: Sunki MIN, Suwon-si (KR)

(73) Assignee: Samsung Electronics Co., Ltd., Suwon-si (KR)

(21) Appl. No.: 18/509,736

(22) Filed: Nov. 15, 2023

(30) Foreign Application Priority Data
Feb. 27, 2023 (KR) 10-2023-0026257

(51) Int. Cl. H01L 27/118

(52) U.S. Cl. CPC H01L 27/11807; H01L 2027/11881

(57) ABSTRACT

A semiconductor device may include a substrate including a first dummy region and a second dummy region spaced apart from each other and a trench between the first dummy region and the second region, a device isolation layer filling the trench between the first dummy region and the second dummy region, a dielectric structure on the device isolation layer; an interlayer dielectric layer on the dielectric structure, a power line on the interlayer dielectric layer, a power delivery network layer on a bottom surface of the substrate, and a through via extending from the power delivery network layer through the dielectric structure to the power line. An upper portion of the device isolation layer may include a protrusion and a trough, and the dielectric structure may cover the protrusion and the trough.

### CROSS-REFERENCE TO RELATED APPLICATION

This U.S. nonprovisional application claims priority under 35 U.S.C § 119 to Korean Patent Application No. 10-2023-0026257 filed on Feb. 27, 2023 in the Korean Intellectual Property Office, the disclosure of which is hereby incorporated by reference in its entirety.

### BACKGROUND

Inventive concepts relate to a semiconductor device and a method of fabricating the same, and more particularly, to a semiconductor device including a field effect transistor and a method of fabricating the same.

A semiconductor device attracts attention as an essential element in electronic industry because of its properties such as compactness, multi-functionality, and/or low manufacturing cost. Semiconductor devices may encompass semiconductor memory devices storing logic data, semiconductor logic devices processing operations of logic data, and hybrid semiconductor devices having both memory and logic elements. Semiconductor devices have been increasingly required for high integration with the advanced development of the electronic industry. For example, semiconductor devices have been increasingly requested for high reliability, high speed, and/or multi-functionality. Semiconductor devices are gradually becoming more complicated and more integrated to meet these requested characteristics.

### SUMMARY

Some embodiments of inventive concepts provide a semiconductor device having increased electrical properties and improved reliability.

Some embodiments of inventive concepts provide a method of fabricating a semiconductor device having increased electrical properties and improved reliability.

According to an embodiment of inventive concepts, a semiconductor device may include may include a substrate including a first dummy region and a second dummy region spaced apart from each other and a trench between the first dummy region and the second dummy region, a device isolation layer filling the trench between the first dummy region and the second dummy region, a dielectric structure on the device isolation layer; an interlayer dielectric layer on the dielectric structure, a power line on the interlayer dielectric layer, a power delivery network layer on a bottom surface of the substrate, and a through via extending from the power delivery network layer through the dielectric structure to the power line. An upper portion of the device isolation layer may include a protrusion and a trough, and the dielectric structure may cover the protrusion and the trough.

According to an embodiment of inventive concepts, a semiconductor device may include a substrate including a first dummy region and a second dummy region spaced apart from each other and a trench between the first dummy region and the second dummy region; a plurality of dummy electrodes on the first dummy region and the second dummy region, respectively; a device isolation layer filling the trench between the first dummy region and the second dummy region; a dielectric structure on the device isolation layer; an interlayer dielectric layer on the dielectric structure; a power line on the interlayer dielectric layer; a power delivery network layer on a bottom surface of the substrate; and a through via extending from the power delivery network layer through the dielectric structure to the power line. An upper portion of the device isolation layer may include a plurality of protrusions. A pitch between the plurality of dummy electrodes may be a first pitch. A pitch between the plurality of protrusions may be a second pitch. The second pitch may be equal to the first pitch.

According to an embodiment of inventive concepts, a semiconductor device may include a logic cell and a tap cell on a substrate; a metal layer on the logic cell and the tap cell, the metal layer including a power line; and a power delivery network layer on a bottom surface of the substrate. The substrate may include a first active region, a second active region, a first dummy region, and a second dummy region. The logic cell may include the first active region and the second active region, a gate electrode on the first active region and the second active region, an active contact adjacent to one side of the gate electrode, and a gate contact coupled to the gate electrode. The tap cell may include the first dummy region and the second dummy region, a dummy electrode on the first dummy region and the second dummy region, a dielectric structure between the first dummy region and the second dummy regions, and a through via that extends from the power delivery network layer through the dielectric structure to the power line. A bottom surface of the dielectric structure may have a wavy profile. The tap cell may be configured to electrically connect the power delivery network layer and the power line to each other through the through via.

### BRIEF DESCRIPTION OF DRAWINGS

FIGS. 1 to 3 illustrate conceptual views showing logic cells of a semiconductor device according to some embodiments of inventive concepts.

FIG. 4 illustrates a plan view showing logic cells and a tap cell of a semiconductor device according to some embodiments of inventive concepts.

FIG. 5 illustrates a plan view showing in detail a first logic cell of FIG. 4.

FIGS. 6A, 6B, 6C, and 6D illustrate cross-sectional views respectively taken along lines A-A′, B-B′, C-C′, and D-D′ of FIG. 5.

FIG. 7 illustrates a plan view showing in detail a tap cell of FIG. 4.

FIGS. 8A and 8B illustrate cross-sectional views respectively taken along lines A-A′ and B-B′ of FIG. 7.

FIGS. 9 to 16 illustrate cross-sectional views taken along line A-A′ of FIG. 7, showing a method of fabricating a semiconductor device according to some embodiments of inventive concepts.

FIGS. 17 and 18 illustrate cross-sectional views taken along line A-A′ of FIG. 7, showing a tap cell according to some embodiments of inventive concepts.

FIGS. 19A, 19B, 19C, and 19D illustrate cross-sectional views respectively taken along lines A-A′, B-B′, C-C′, and D-D′ of FIG. 5, showing a semiconductor device according to some embodiments of inventive concepts.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

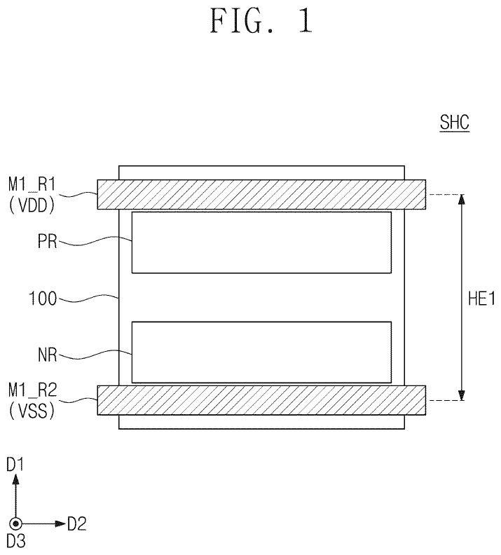

FIGS. 1 to 3 illustrate conceptual views showing logic cells of a semiconductor device according to some embodiments of inventive concepts.

Referring to FIG. 1, a single height cell SHC may be provided. For example, a substrate 100 may be provided thereon with a first power line M1_R1 and a second power line M1_R2. The first power line M1_R1 may be a path for providing a drain voltage VDD, for example, a power voltage. The second power line M1_R2 may be a path for providing a source voltage VSS, for example, a ground voltage.

The single height cell SHC may be defined between the first power line M1_R1 and the second power line M1_R2. The single height cell SHC may include one first active region PR and one second active region NR. For example, the first active region PR may be a PMOSFET region, and the second active region NR may be an NMOSFET region. For example, the single height cell SHC may have a complementary metal oxide semiconductor (CMOS) structure provided between the first power line M1_R1 and the second power line M1_R2.

The first active region PR and the second active region NR may have the same width in a first direction D1. A first height HE1 may be defined to indicate a length in the first direction D1 of the single height cell SHC. The first height HE1 may be the same or substantially the same as a distance (e.g., pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. For example, the logic cell may include transistors for constituting a logic device, and may also include wiring lines that connect the transistors to each other.

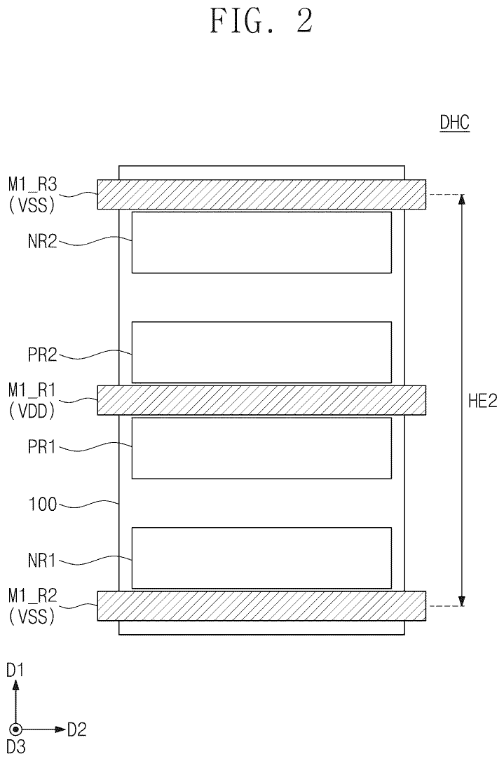

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage VSS.

The double height cell DHC may be defined between the second power line M1_R2 and the third power line M1_R3. The double height cell DHC may include first and second PMOSFET regions PR1 and PR2 and first and second NMOSFET regions NR1 and NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to opposite sides of the first power line M1_R1. When viewed in plan, the first power line M1_R1 may be located between the first and second PMOSFET regions PR1 and PR2.

A second height HE2 may be defined to indicate a length in the first direction D1 of the double height cell DHC. The second height HE2 may be about twice the first height HE1 of FIG. 1. The first and second PMOSFET regions PR1 and PR2 of the double height cell DHC may collectively operate as a single PMOSFET region. Therefore, the double height cell DHC may have a PMOS transistor whose channel size is greater than that of a PMOS transistor included in the single height cell SHC discussed above in FIG. 1.

For example, the channel size of the PMOS transistor included in the double height cell DHC may be about twice that of the PMOS transistor included in the single height cell SHC. In conclusion, the double height cell DHC may operate at a higher speed than that of the single height cell SHC. In inventive concepts, the double height cell DHC shown in FIG. 2 may be defined as a multi-height cell. Although not shown, the multi-height cell may include a triple height cell whose cell height is about three times that of the single height cell SHC.

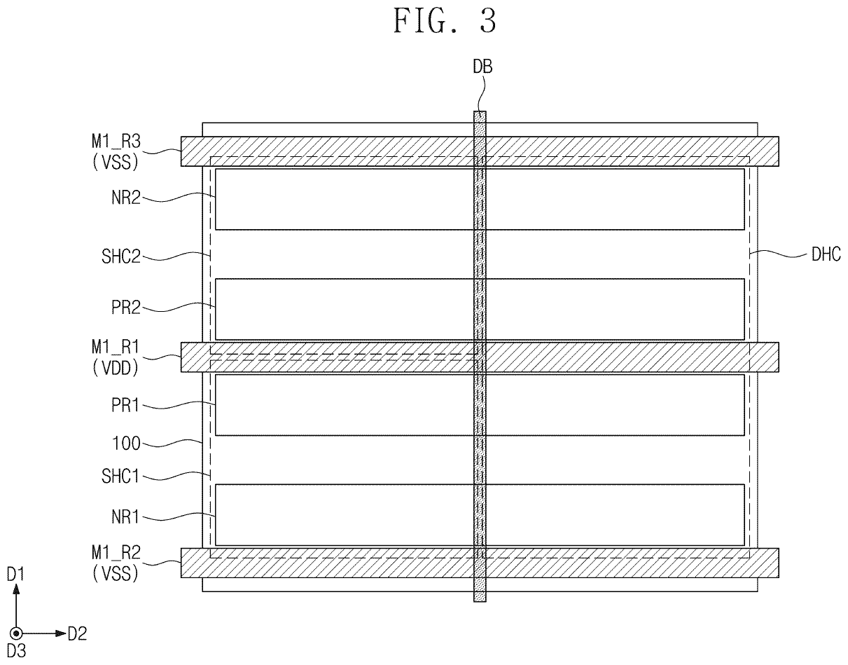

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

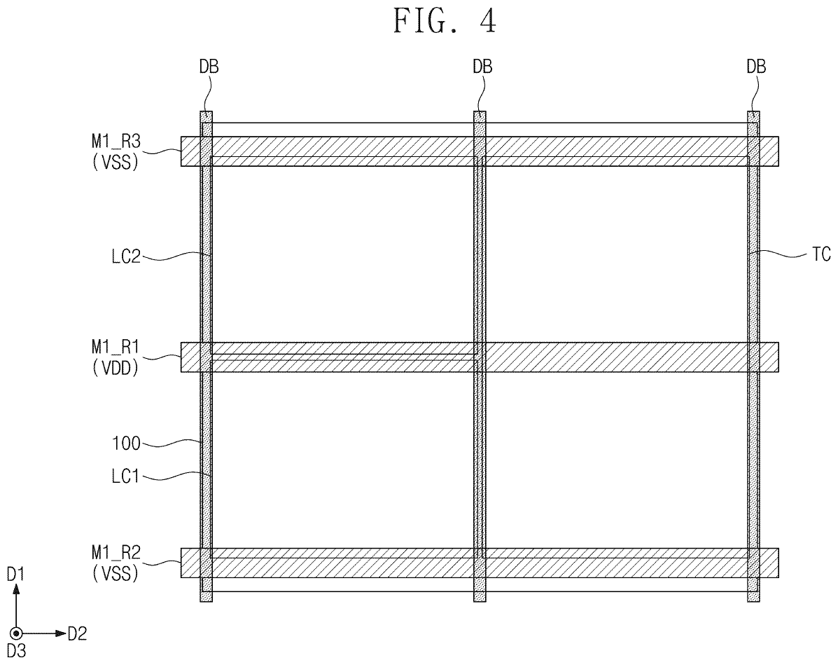

FIG. 4 illustrates a plan view showing logic cells and a tap cell of a semiconductor device according to some embodiments of inventive concepts. Referring to FIG. 4, a first logic cell LC1, a second logic cell LC2, and a tap cell TC may be two-dimensionally disposed on a substrate 100. For example, the first logic cell LC1 may be disposed on a position where the first single height cell SHC1 of FIG. 3 is located, the second logic cell LC2 may be disposed on a position where the second single height cell SHC2 of FIG. 3 is located, and the tap cell TC may be disposed on a position where the double height cell DHC of FIG. 3 is located.

The tap cell TC may be a cell for applying a voltage to at least one of the first and third power lines M1_R1 and M1_R3 from a power delivery network which will be discussed below. Different from the first and second logic cells LC1 and LC2, the tap cell TC may include no logic device. For example, the tap cell TC may be a kind of dummy cell that performs a function of applying a voltage to a power line and does not perform a circuit function.

As shown in FIG. 4, the tap cell TC may be disposed between logic cells in a cell region where logic cells are located. FIG. 4 depicts by way of example an arrangement relationship between the tap cell TC and the first and second logic cells LC1 and LC2.

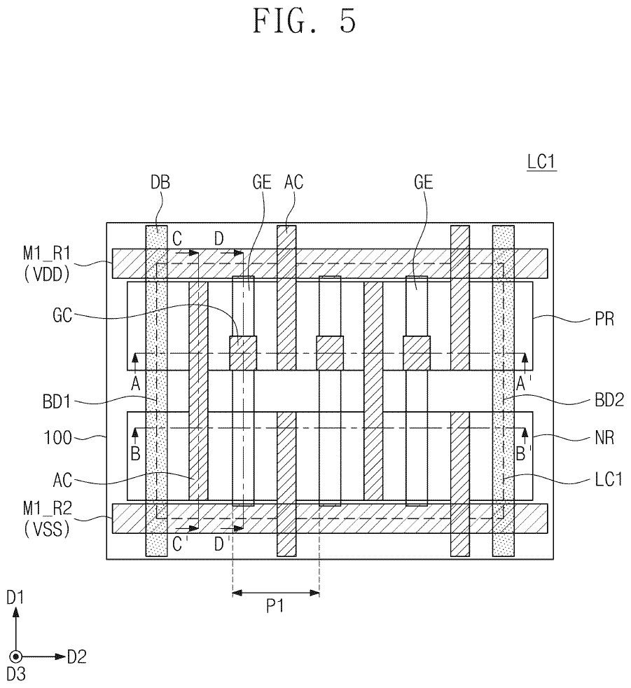

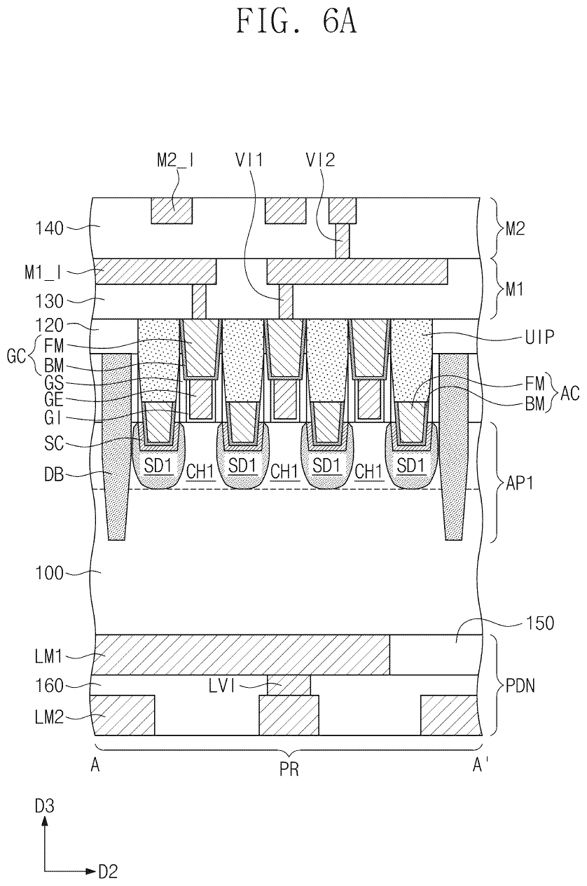

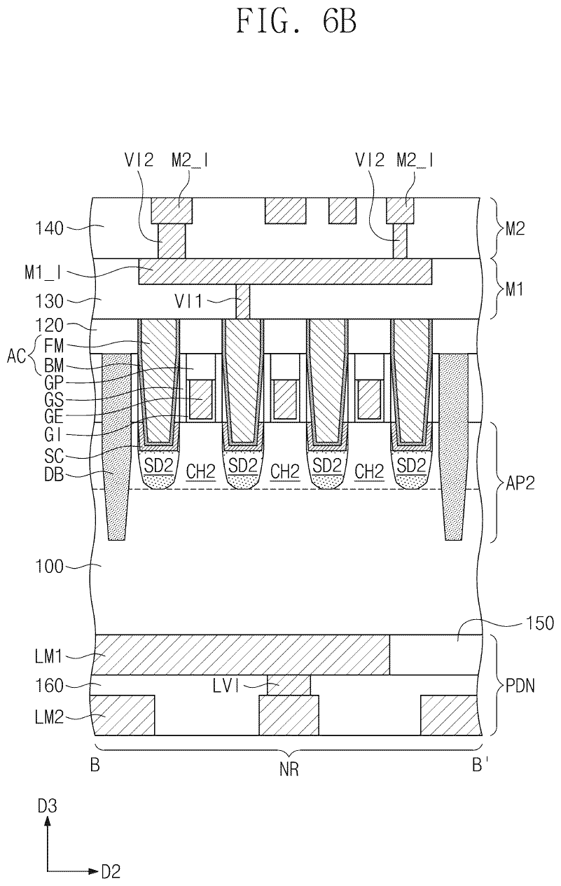

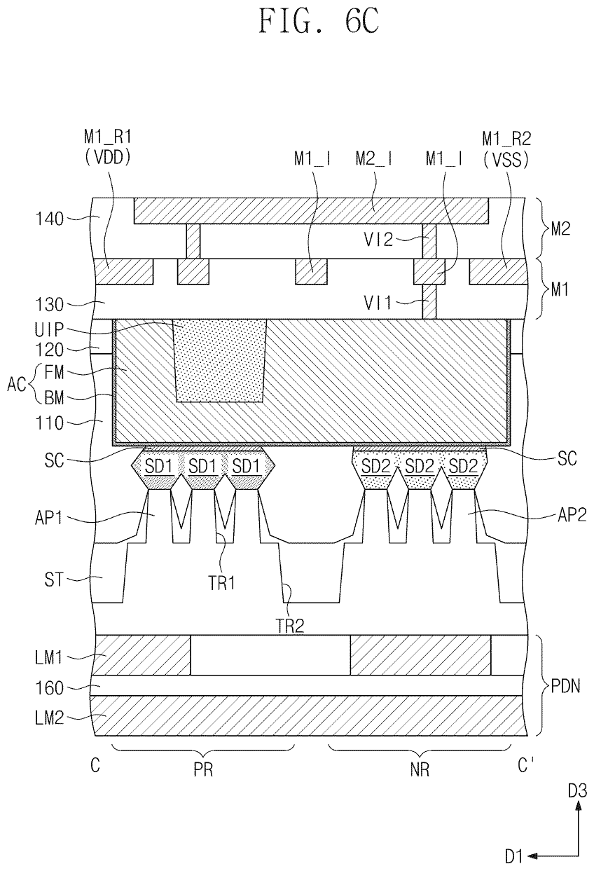

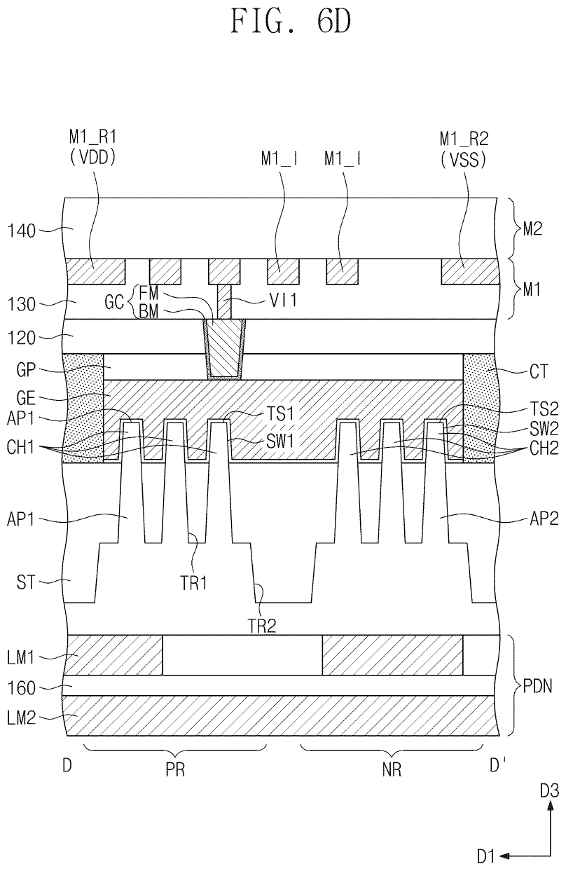

FIG. 5 illustrates a plan view showing in detail a first logic cell of FIG. 4. FIGS. 6A, 6B, 6C, and 6D illustrate cross-sectional views respectively taken along lines A-A′, B-B′, C-C′, and D-D′ of FIG. 5. The following will describe in detail the first logic cell LC1 with reference to FIGS. 5 and 6A to 6D.

The substrate 100 may include a first active region PR and a second active region NR. In an embodiment of inventive concepts, the first active region PR may be a PMOSFET region, and the second active region NR may be an NMOSFET region. The substrate 100 may be a compound semiconductor substrate or a semiconductor substrate including silicon, germanium, or silicon-germanium. For example, the substrate 100 may be a silicon substrate.

The first active region PR and the second active region NR may be defined by a second trench TR2 formed on an upper portion of the substrate 100. The second trench TR2 may be positioned between the first active region PR and the second active region NR. The first active region PR and the second active region NR may be spaced apart from each other in a first direction D1 across the second trench TR2. Each of the first and second active regions PR and NR may extend in a second direction D2 that intersects the first direction D1.

First active patterns AP1 and second active patterns AP2 may be respectively provided on the first active region PR and the second active region NR. The first and second active patterns AP1 and AP2 may parallel extend in the second direction D2. The first and second active patterns AP1 and AP2 may be vertically protruding portions of the substrate 100. A first trench TR1 may be defined between neighboring first active patterns AP1 and between neighboring second active patterns AP2. The first trench TR1 may be shallower than the second trench TR2.

A device isolation layer ST may fill the first and second trenches TR1 and TR2. The device isolation layer ST may include a silicon oxide layer. The first and second active patterns AP1 and AP2 may have their upper portions that vertically protrude upwards from the device isolation layer ST (see FIG. 6D). Each of the first and second active patterns AP1 and AP2 may have a fin shape at the upper portion thereof. The device isolation layer ST may not cover any of the upper portions of the first and second active patterns AP1 and AP2. The device isolation layer ST may cover lower sidewalls of the first and second active patterns AP1 and AP2.

First source/drain patterns SD1 may be provided on the upper portions of the first active patterns AP1. The first source/drain patterns SD1 may be impurity regions having a first conductivity type (e.g., p-type). A first channel pattern CH1 may be interposed between a pair of first source/drain patterns SD1. Second source/drain patterns SD2 may be provided on the upper portions of the second active patterns AP2. The second source/drain patterns SD2 may be impurity regions having a second conductivity type (e.g., n-type). A second channel pattern CH2 may be interposed between a pair of second source/drain patterns SD2.

The first and second source/drain patterns SD1 and SD2 may be epitaxial patterns formed by a selective epitaxial growth process. For example, the first and second source/drain patterns SD1 and SD2 may have their top surfaces coplanar with those of the first and second channel patterns CH1 and CH2. For another example, the first and second source/drain patterns SD1 and SD2 may have their top surfaces higher than those of the first and second channel patterns CH1 and CH2.

The first source/drain patterns SD1 may include a semiconductor element (e.g., SiGe) whose lattice constant is greater than that of a semiconductor element of the substrate 100. Therefore, the first source/drain patterns SD1 may provide the first channel patterns CH1 with compressive stresses. For example, the second source/drain patterns SD2 may include the same semiconductor element (e.g., Si) as that of the substrate 100.

Gate electrodes GE may be provided to extend in the first direction D1, while running across the first and second active patterns AP1 and AP2. The gate electrodes GE may be arranged along the second direction D2 at a first pitch P1 (see FIG. 5). The gate electrodes GE may vertically overlap the first and second channel patterns CH1 and CH2. Each of the gate electrodes GE may surround the top surface and opposite sidewalls of each of the first and second channel patterns CH1 and CH2.

Referring back to FIG. 6D, the gate electrode GE may be provided on a first top surface TS1 of the first channel pattern CH1 and at least one first sidewall SW1 of the first channel pattern CH1. The gate electrode GE may be provided on a second top surface TS2 of the second channel pattern CH2 and at least one second sidewall SW2 of the second channel pattern CH2. For example, a transistor according to the present embodiment may be a three-dimensional field effect transistor (e.g., FinFET) in which the gate electrode GE three-dimensionally surrounds the first and second channel patterns CH1 and CH2.

Referring back to FIGS. 5 and 6A to 6D, a pair of gate spacers GS may be disposed on opposite sidewalls of each of the gate electrodes GE. The gate spacer GS may extend in the first direction D1 along the gate electrode GE. The gate spacer GS may have a top surface higher than that of the gate electrode GE. The top surface of the gate spacer GS may be coplanar with that of a first interlayer dielectric layer 110 which will be discussed below. The gate spacer GS may include at least one selected from SiCN, SiCON, and SiN. Alternatively, the gate spacer GS may include a multiple layer formed of at least two selected from SiCN, SiCON, and SiN.

A gate capping pattern GP may be provided on each of the gate electrodes GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be interposed between the gate electrode GE and the first active pattern AP1 and between the gate electrode GE and the second active pattern AP2. The gate dielectric layer GI may extend along a bottom surface of the gate electrode GE that overlies the gate dielectric layer GI. For example, the gate dielectric layer GI may cover the first top surface TS1 and the first sidewall SW1 of the first channel pattern CH1. The gate dielectric layer GI may cover the second top surface TS2 and the second sidewall SW2 of the second channel pattern CH2. The gate dielectric layer GI may cover a top surface of the device isolation layer ST that underlies the gate electrode GE (see FIG. 6D).

The gate dielectric layer GI may include a high-k dielectric layer whose dielectric constant is greater than that of a silicon oxide layer. For example, the high-k dielectric layer may include at least one selected from hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. In an embodiment of inventive concepts, the gate dielectric layer GI may include a silicon oxide layer and a high-k dielectric layer that are sequentially stacked.

The gate electrode GE may include a first metal pattern and a second metal pattern on the first metal pattern. The first metal pattern may be provided on the gate dielectric layer GI and may be adjacent to the first and second channel patterns CH1 and CH2. The first metal pattern may include a work-function metal that controls a threshold voltage of a transistor. A thickness and composition of the first metal pattern may be adjusted to achieve a desired threshold voltage.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). The first metal pattern may further include carbon (C). The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta).

Referring back to FIG. 6D, cutting patterns CT may be provided on opposite ends of the gate electrode GE. The cutting pattern CT may separate the gate electrode GE of the first logic cell LC1 from the gate electrode GE of the second logic cell LC2. The cutting pattern CT may include a dielectric material, such as a silicon oxide layer and/or a silicon nitride layer.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with those of the gate capping patterns GP and those of the gate spacers GS. The first interlayer dielectric layer 110 may be provided thereon with a second interlayer dielectric layer 120 that covers the gate capping patterns GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

A pair of separation structures DB may be provided on opposite boundaries of the first logic cell LC1 that face each other in the second direction D2. The separation structure DB may extend in the first direction D1 parallel to the gate electrodes GE.

The separation structure DB may penetrate the gate capping pattern GP and the gate electrode GE to extend into the first and second active patterns AP1 and AP2. The separation structure DB may penetrate an upper portion of each of the first and second active patterns AP1 and AP2. The separation structure DB may separate the first and second active regions PR and NR of the first logic cell LC1 from active regions of an adjacent logic cell.

Active contacts AC may be provided to penetrate the first and second interlayer dielectric layers 110 and 120 and to have electrical connection with the first and second source/drain patterns SD1 and SD2. For example, the active contact AC of the first logic cell LC1 may be provided between the gate electrode GE and the separation structure DB. The active contact AC may extend in the first direction D1 to connect the second source/drain pattern SD2 to the first source/drain pattern SD1 (see FIG. 6C).

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not shown, the active contact AC may cover a portion of the top surface of the gate capping pattern GP.

A silicide pattern SC may be interposed between the active contact AC and the first source/drain pattern SD1 and between the active contact AC and the second source/drain pattern SD2. The active contact AC may be electrically connected through the silicide pattern SC to the first and second source/drain patterns SD1 and SD2. The silicide pattern SC may include metal silicide, for example, at least one selected from titanium silicide, tantalum silicide, tungsten silicide, nickel silicide, and cobalt silicide.

Gate contacts GC may be provided to penetrate the second interlayer dielectric layer 120 and the gate capping pattern GP and to have electrical connections with corresponding gate electrodes GE. For example, referring to FIG. 6a, the active contact AC may have an upper portion adjacent to the gate contact GC, and an upper dielectric pattern UIP may fill the upper portion of the gate contact GC. Therefore, it may be possible to limit and/or prevent the occurrence of short-circuit caused by contact between the gate contact GC and its adjacent active contact AC.

Each of the active contact AC and the gate contact GC may include a conductive pattern FM and a barrier pattern BM that surrounds the conductive pattern FM. For example, the conductive pattern FM may include at least one metal selected from aluminum, copper, tungsten, molybdenum, and cobalt. The barrier pattern BM may cover sidewalls and a bottom surface of the conductive pattern FM. The barrier pattern BM may include a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

A first metal layer M1 may be provided in the third interlayer dielectric layer 130. The first metal layer M1 of the first logic cell LC1 may include a first power line M1_R1, a second power line M1_R2, and first wiring lines M1_I between the first and second power lines M1_R1 and M1_R2.

The first power line M1_R1 and the second power line M1_R2 may each extend in the second direction D2, while running across the first logic cell LC1. The first wiring lines M1_I may be disposed between the first and second power lines M1_R1 and M1_R2. The first wiring lines M1_I may each have a linear or bar shape that extends in the second direction D2.

The first metal layer M1 may further include first vias VI1. Each of the first vias VI1 may be provided below a wiring line of the first metal layer M1. For example, the first via VI1 may be interposed between and electrically connect the active contact AC and the first wiring line M1_I. The first via VI1 may be interposed between and electrically connect the active contact AC and the power line M1_R1 or M1_R2. The first via VI1 may be interposed between and electrically connect the gate contact GC and the first wiring line M1_I.

A certain line and its underlying first via VI1 of the first metal layer M1 may be formed by individual processes. For example, the certain line and its underlying first via VI1 of the first metal layer M1 may each be formed by a single damascene process. A sub-20 nm process may be employed to fabricate a semiconductor device according to some embodiments.

A second metal layer M2 may be provided in the fourth interlayer dielectric layer 140. The second metal layer M2 may include second wiring lines M2_I. The second wiring lines M2_I of the second metal layer M2 may each have a linear or bar shape that extends in the first direction D1. For example, the second wiring lines M2_I may parallel extend in the first direction D1.

The second metal layer M2 may further include second vias VI2. The second vias VI2 may be correspondingly provided below the second wiring lines M2_I. The second wiring line M2_I may be electrically connected through the second via VI2 to the first wiring line M1_I.

The second wiring line M2_I and its underlying second via VI2 of the second metal layer M2 may be formed into a single piece in the same process. For example, a dual damascene process may be employed to simultaneously form the second wiring line M2_I and the second via VI2 of the second metal layer M2.

The first and second metal layers M1 and M2 may have their wiring lines that include the same or different conductive materials. For example, the first and second metal layers M1 and M2 may have their wiring lines that include at least one metallic material selected from aluminum, copper, tungsten, molybdenum, and cobalt. Although not shown, the fourth interlayer dielectric layer 140 may be additionally provided thereon with stacked metal layers (e.g., M3, M4, M5, M6, M7, etc.). Each of the stacked metal layers may include lines for routing.

A power delivery network layer PDN may be provided on a bottom surface of the substrate 100. The power delivery network layer PDN may include a fifth interlayer dielectric layer 150 and a sixth interlayer dielectric layer 160 that are sequentially stacked on the bottom surface of the substrate 100.

The power delivery network layer PDN may further include first lower lines LM1 and second lower lines LM2. The first lower lines LM1 may be provided in the fifth interlayer dielectric layer 150, and the second lower lines LM2 may be provided in the sixth interlayer dielectric layer 160. A lower via LVI may be provided between the first and second lower lines LM1 and LM2.

The power delivery network layer PDN may include a wiring network for applying a drain voltage VDD to the first power line M1_R1. The power delivery network layer PDN may include a wiring network for applying a source voltage VSS to the second power line M1_R2. Although not shown, lower metal layers may be additionally disposed below the sixth interlayer dielectric layer 160.

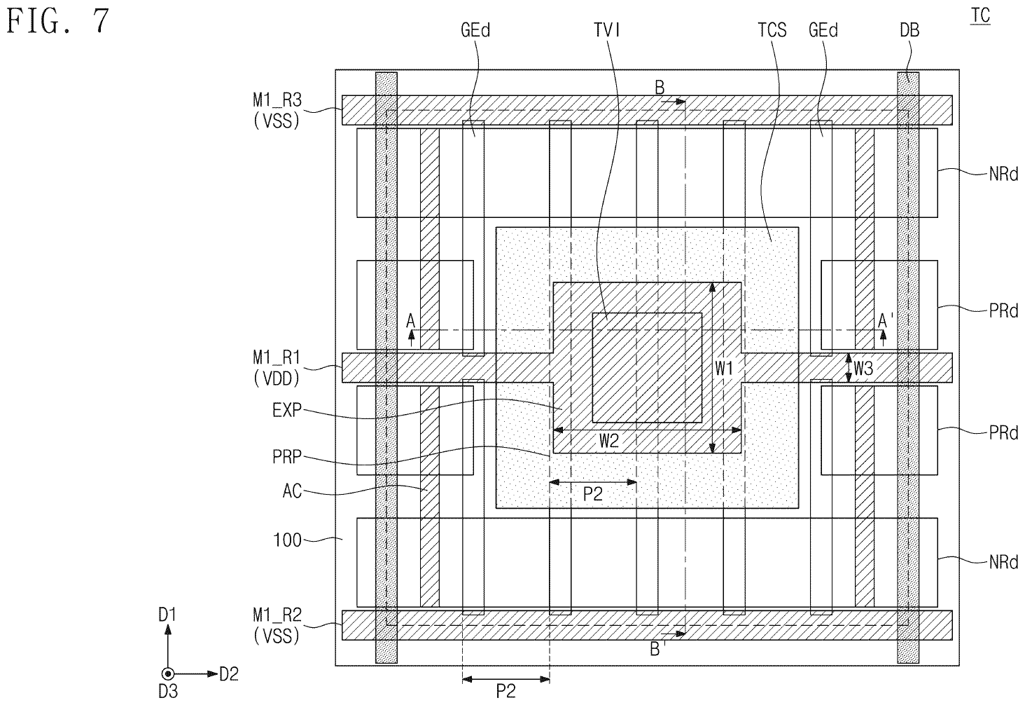

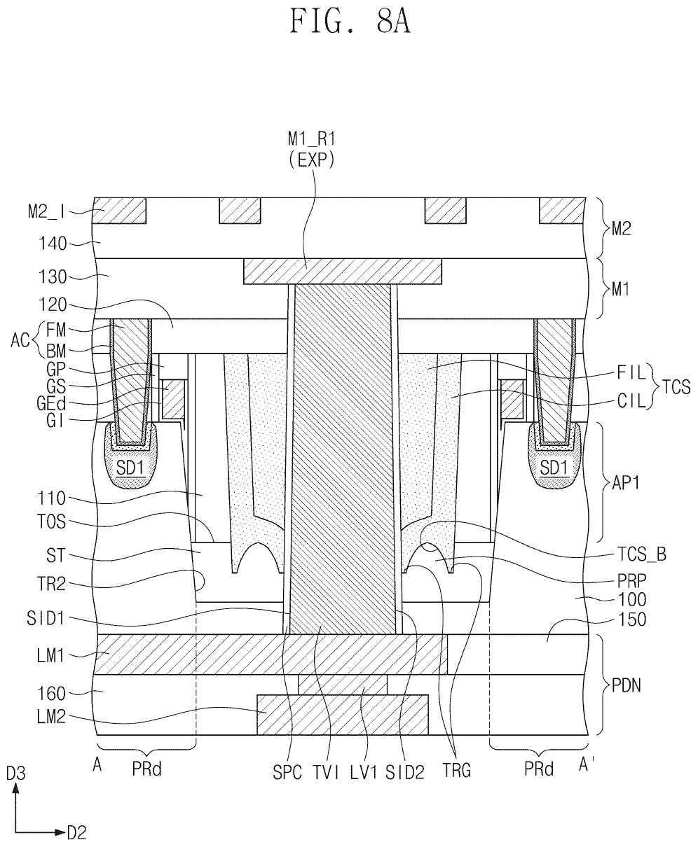

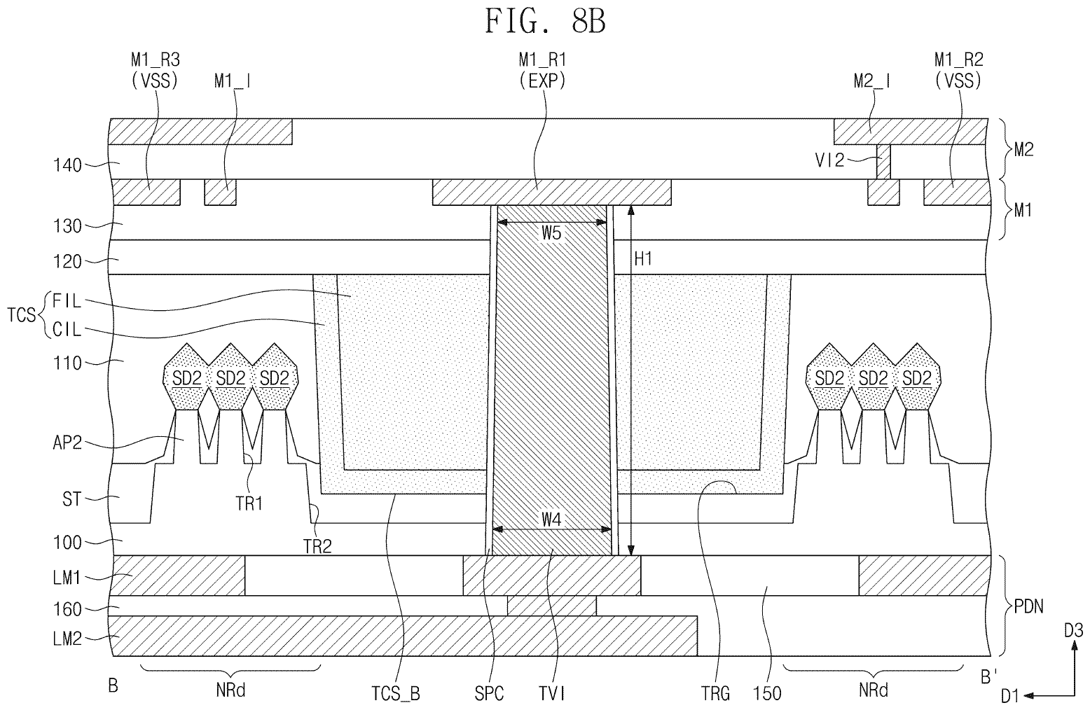

FIG. 7 illustrates a plan view showing in detail a tap cell of FIG. 4. FIGS. 8A and 8B illustrate cross-sectional views respectively taken along lines A-A′ and B-B′ of FIG. 7. The tap cell TC will be further discussed in detail below with reference to FIGS. 7, 8A, and 8B. In the embodiment that follows, a description of features repetitive to those mentioned about the first logic cell LC1 will be omitted, and a difference thereof will be discussed in detail.

The tap cell TC may include at least one first dummy region PRd and at least one second dummy region NRd. The first dummy region PRd may have a structure on the substrate 100 the same as that of the first active region PR discussed above, but may not constitute a logic circuit. The second dummy region NRd may have the same structure on the substrate 100 as that of the second active region NR discussed above, but may not constitute a logic circuit.

The first and second dummy regions PRd and NRd may serve as a buffer between logic cells (e.g., the first logic cell LC1 and the second logic cell LC2) adjacent to the tap cell TC. It may be possible to reduce an electrical effect that the tap cell LC has on peripheral logic cells through the first and second dummy regions PRd and NRd.

Dummy electrodes GEd may be provided on the first and second dummy regions PRd and NRd. The dummy electrodes GEd may be arranged along the second direction D2 at a second pitch P2 (see FIG. 7). The second pitch P2 may be the same or substantially the same as the first pitch P1 between the gate electrodes GE. The dummy electrode GEd may have the same structure as that of the gate electrode GE discussed above, but may not constitute a logic circuit.

At least one active contact AC may be provided on the at least one first and second dummy regions PRd and NRd. The at least one active contact AC in the tap cell TC may not be connected to the first metal layer M1. For example, the at least one active contact AC in the tap cell TC may be a dummy contact.

An extension EXP may be included in at least one power line, such as the first power line M1_R1, in the tap cell TC. The first and second dummy regions PRd and NRd may be spaced apart at a certain distance from the extension EXP. For example, the extension EXP of the first power line M1_R1 may not overlap any of the first and second dummy regions PRd and NRd. The extension EXP of the first power line M1_R1 may be provided on the device isolation layer ST that fills the second trench TR2.

The extension EXP may allow the first power line M1_R1 to have an increased width in the first direction D1. For example, the extension EXP may have a first width W1 in the first direction D1 and a second width W2 in the second direction D2. The first width W2 may be the same as or different from the second width W2. For example, the first width W1 may be less than the second width W2 The first width W1 may be about 3 times to about 10 times a line-width W3 of the first power line M1_R1. The first width W1 may be about 1.5 times to about 7 times the first pitch P1. The second width W2 may be about 2 times to about 8 times the first pitch P1.

The tap cell TC may include a through via TVI that penetrate the substrate 100 to extend from the power delivery network layer PDN to the extension EXP of the first power line M1_R1. The through via TVI may have a pillar shape that extends in a vertical direction or a third direction D3. The through via TVI may have a bottom surface connected to the first lower line LM1. The through via TVI may have a top surface connected to the extension EXP of the first power line M1_R1. Although not shown, a via (or contact) may be interposed between the through via TVI and the first lower line LM1.

The first lower lines LM1 of the power delivery network layer PDN may be electrically connected via the through via TVI to the first power line M1_R1 of the first metal layer M1. In such a configuration, a voltage may be applied from the power delivery network layer PDN via the through via TVI to a power line of the first metal layer M1. The tap cell TC according to the present embodiment may be a power tap cell that applies a power from the power delivery network layer PDN to a power line of the first metal layer M1.

The through via TVI may vertically overlap the extension EXP. The through via TVI may sequentially penetrate the substrate 100, the device isolation layer ST, a dielectric structure TCS, and the second and third interlayer dielectric layers 120 and 130. The through via TVI may be provided between the first dummy regions PRd that are adjacent to each other in the second direction D2. The through via TVI may be provided between the second dummy regions NRd that are adjacent to each other in the first direction D1.

The through via TVI may have a width that decreases in a direction from the power delivery network layer PDN to the first metal layer M1. The through via TVI may have a fourth width W4 at its lower portion greater than a fifth width W5 at its upper portion (see FIG. 8B). For example, the fourth width W4 may be about 1.2 times to about 2 times the fifth width W5. The through via TVI may have an inclined sidewall. For example, an angle θ1 of about 85° to about 89.5° may be made between the sidewall of the through via TVI and the bottom surface of the substrate 100.

The through via TVI may include at least one metal selected from aluminum, copper, tungsten, ruthenium, molybdenum, and cobalt. In an embodiment of inventive concepts, the through via TVI may further include a barrier layer. The barrier layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

A spacer SPC may be provided on the sidewall of the through via TVI. For example, the spacer SPC may be interposed between the through via TVI and the dielectric structure TCS. The spacer SPC may include a silicon-based dielectric material (e.g., a silicon oxide layer, a silicon nitride layer, or a silicon oxynitride layer).

According to some embodiments of inventive concepts, power delivery lines may be omitted from stacked metal layers (e.g., M2, M3, M4, M5, M6, M7, etc.), and instead, the power delivery network layer PDN may be disposed on the bottom surface of the substrate 100. Accordingly, a semiconductor device may increase in integration, and the stacked metal layers (e.g., M2, M3, M4, M5, M6, M7, etc.) may increase in the degree of freedom of routing.

In inventive concepts, as the tap cell TC is disposed in a cell region where the logic cells LC are located, voltages may be stably applied from the power delivery network layer PDN to the power lines M1_R1 to M1_R3. In addition, the tap cell TC includes the dummy region PRd or NRd that functions as a buffer, there may be a reduced effect on the active region PR or NR of an adjacent logic cell LC.

According to the present embodiment, a power line in the tap cell TC may include the extension EXP. As the extension EXP is formed to have a width greater than that of the through via TVI, the through via TVI having a relatively large diameter may be stably coupled to a power line.

The dielectric structure TCS may be provided on a center of the tap cell TC. In an embodiment, the through via TVI may penetrate a center of the dielectric structure TCS. When viewed in plan, the dielectric structure TCS may be disposed between the first and second dummy regions PRd and NRd (see FIG. 7). The dielectric structure TCS may be provided on the device isolation layer ST that fills the second trench TR2.

The device isolation layer ST may include a plurality of protrusions PRP that vertically protrude toward the dielectric structure TCS. Referring back to FIG. 7, in an embodiment of inventive concepts, the protrusions PRP of the device isolation layer ST may be correspondingly aligned in the first direction D1 with the dummy electrodes GEd. For example, the protrusions PRP may be structures formed by the dummy electrodes GEd positioned on the center of the tap cell TC. A pitch between neighboring protrusions PRP may be the same or substantially the same as the second pitch P2.

A trough TRG may be provided on each of opposite sides of the protrusion PRP. For example, the trough TRG may be defined between neighboring protrusions PRP. The trough TRG may be located at a height (or level) lower than that of a top surface TOS of the device isolation layer ST.

Referring to FIG. 8A, the through via TVI may have a first side SID1 and a second side SID2 that are opposite to each other in the second direction D2. One protrusion PRP may be adjacent to the first side SID1 of the through via TVI. The trough TRG may be positioned between the protrusion PRP and the first side SID1 of the through via TVI. One protrusion PRP may be adjacent to the second side SID2 of the through via TVI. The trough TRG may be positioned between the protrusion PRP and the second side SID2 of the through via TVI.

Referring back to FIGS. 7, 8A, and 8B, the dielectric structure TCS may include a first dielectric structure CIL and a second dielectric structure FIL on the first dielectric structure CIL. The first dielectric structure CIL may have a conformal thickness. The first dielectric structure CIL may directly cover the trough TRG and the protrusion PRP of the device isolation layer ST. The second dielectric structure FIL may fill an inside of the first dielectric structure CIL. As the dielectric structure TCS covers the protrusions PRP and the troughs TRG, a bottom surface TCS_B of the dielectric structure TCS may have a wavy profile in the second direction D2. As shown in FIG. 8B, the bottom surface TCS_B of the dielectric structure TCS may have a flat profile in the first direction D1.

Each of the first and second dielectric structures CIL and FIL may include a silicon-based dielectric material (e.g., a silicon oxide layer, a silicon nitride layer, or a silicon oxynitride layer). For example, the first and second dielectric structures CIL and FIL may include a silicon oxide layer.

According to some embodiments of inventive concepts, the dummy electrodes GEd in a region where the through via TVI will be formed may be replaced with the dielectric structure TCS. Thus, it may be possible to limit and/or prevent process failure that occurs in an etching process for forming the through via TVI. Thus, only one through via TVI may be enough to directly connect the first power line M1_R1 of the first metal layer M1 to the first lower line LM1 of the power delivery network layer PDN. A semiconductor device according to inventive concepts may be superior in terms of reliability, process efficiency, and electrical properties.

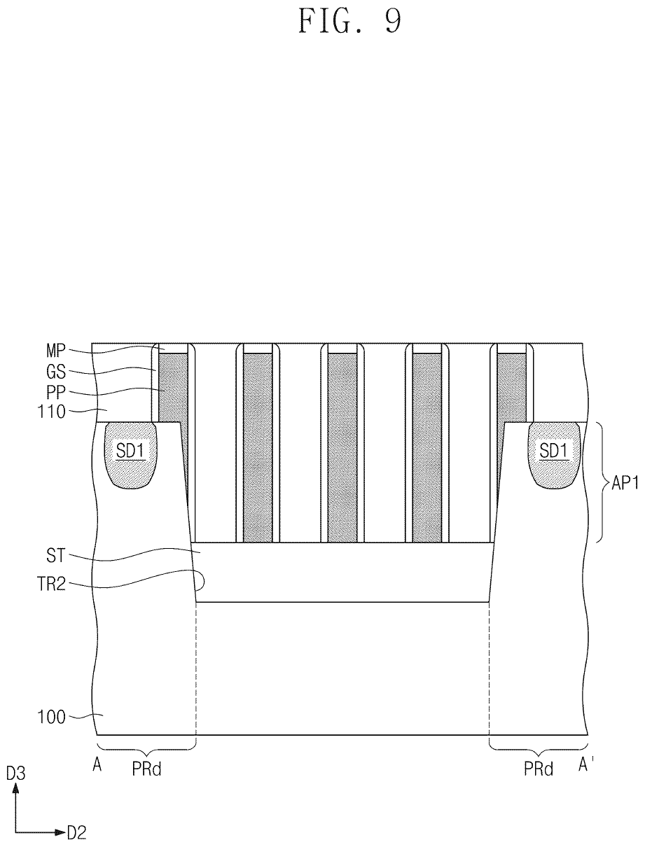

FIGS. 9 to 16 illustrate cross-sectional views taken along line A-A′ of FIG. 7, showing a method of fabricating a semiconductor device according to some embodiments of inventive concepts.

Referring to FIGS. 7 and 9, a substrate 100 may be patterned to form first and second dummy regions PRd and NRd. At the same time when the first and second dummy regions PRd and NRd are formed, first and second trenches TR1 and TR2 may be formed on the substrate 100. The first and second trenches TR1 and TR2 may define the first and second dummy regions PRd and NRd.

A device isolation layer ST may be formed to fill the first and second trenches TR1 and TR2. A dielectric layer may be formed on an entire surface of the substrate 100, covering the first and second dummy regions PRd and NRd. The dielectric layer may be recessed until upper portions of the first and second dummy regions PRd and NRd are exposed, thereby forming the device isolation layer ST. The device isolation layer ST may include a dielectric material, such as a silicon oxide layer.

Sacrificial patterns PP may be formed on the substrate 100, running across the first and second dummy regions PRd and NRd. Each of the sacrificial patterns PP may be formed to have a linear or bar shape that extends in a first direction D1. The sacrificial patterns PP may be arranged at a first pitch along a second direction D2.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. The sacrificial layer may include polysilicon.

A pair of gate spacers GS may be formed on opposite sidewalls of each of the sacrificial patterns PP. The formation of the gate spacers GS may include conformally forming a gate spacer layer on the entire surface of the substrate 100 and anisotropically etching the gate spacer layer. The gate spacer layer may include at least one selected from SiCN, SiCON, and SiN. Alternatively, the gate spacer layer may be a multiple layer including at least two selected from SiCN, SiCON, and SiN.

First and second source/drain patterns SD1 and SD2 may be formed on upper portions of the first and second dummy regions PRd and NRd. Each of the first and second source/drain patterns SD1 and SD2 may be formed between neighboring sacrificial patterns PP. In an embodiment of inventive concepts, the first and second source/drain patterns SD1 and SD2 may be formed by a selective epitaxial growth process.

A first interlayer dielectric layer 110 may be formed to cover the first and second source/drain patterns SD1 and SD2, the hardmask patterns MP, and the gate spacers GS. For example, the first interlayer dielectric layer 110 may include a silicon oxide layer.

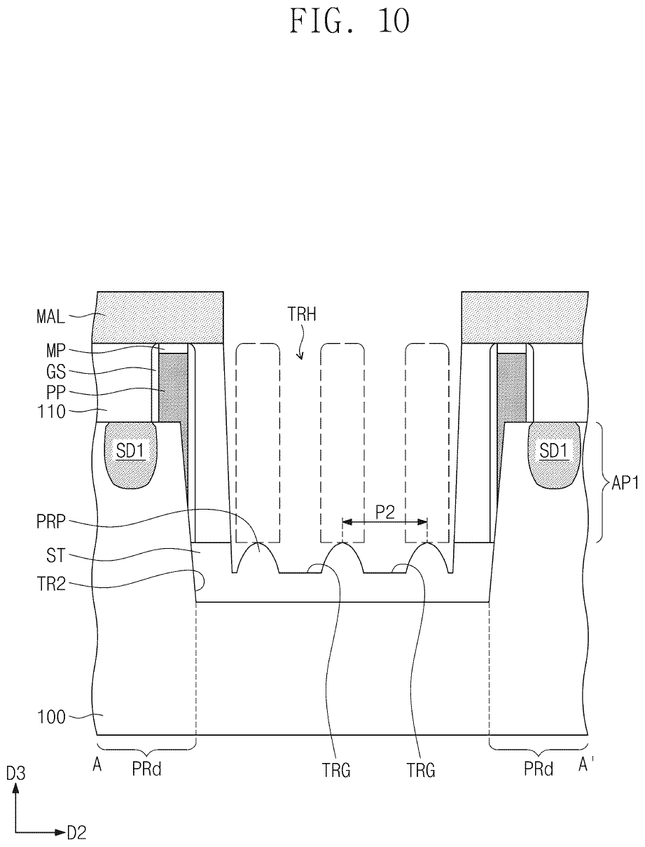

Referring to FIGS. 7 and 10, a through hole TRH may be formed on the first interlayer dielectric layer 110, penetrating a central portion of a tap cell TC. A planar shape of the through hole TRH may be the same or substantially the same as that of the dielectric structure TCS depicted in FIG. 7.

For example, a mask layer MAL may be formed on the first interlayer dielectric layer 110 to define the through hole TRH. The mask layer MAL may be formed by a photolithography process. The mask layer MAL may be used as an etching mask to perform an anisotropic etching process to form the through hole TRH. The anisotropic etching process may remove all of the hardmask pattern MP, the gate spacer GS, the sacrificial pattern PP, the first interlayer dielectric layer 110, and the device isolation layer ST that are exposed by the mask layer MAL. The anisotropic etching process may continue until a bottom surface of the second trench TR2 is exposed.

The anisotropic etching process may cause that only the device isolation layer ST at bottom may be left and exposed. During the anisotropic etching process, there may occur a difference in etch selectivity between the sacrificial pattern PP and the first interlayer dielectric layer 110. Thus, a protrusion PRP may be formed on an upper portion of the device isolation layer ST that overlaps the sacrificial pattern PP. A trough TRG may be formed on an upper portion of the device isolation layer ST that overlaps the first interlayer dielectric layer 110.

In some embodiments of inventive concepts, the protrusion PRP may be created on a region that overlaps the first interlayer dielectric layer 110. The trough TRG may be created on a region that overlaps the sacrificial pattern PP. This may be caused by the fact that, in accordance with an etch recipe of the anisotropic etching process, an etch rate of the first interlayer dielectric layer 110 is less than an etch rate of the sacrificial pattern PP.

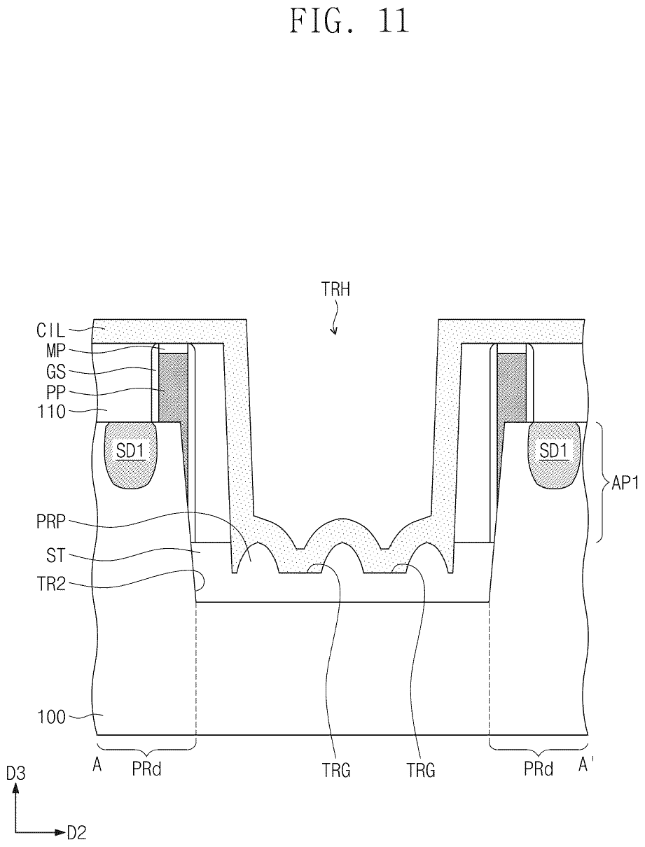

Referring to FIGS. 7 and 11, a first dielectric structure CIL may be conformally formed in the through hole TRH. The first dielectric structure CIL may directly cover the trough TRG and the protrusion PRP of the device isolation layer ST. For example, the first dielectric structure CIL may be formed by atomic layer deposition (ALD) or chemical vapor deposition (CVD). The first dielectric structure CIL may be formed of a silicon-based dielectric material (e.g., a silicon oxide layer, a silicon nitride layer, or a silicon oxynitride layer). The first dielectric structure CIL may not completely but partially fill the through hole TRH.

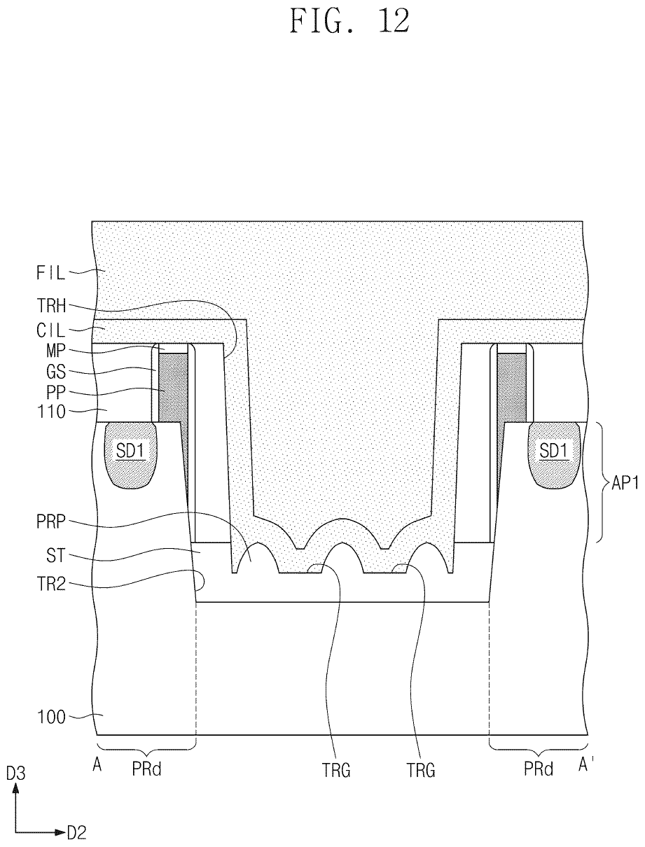

Referring to FIGS. 7 and 12, a second dielectric structure FIL may be formed on the first dielectric structure CIL, filling the through hole TRH. The second dielectric structure FIL may be formed by a deposition process with superior filling characteristics. For example, the second dielectric structure FIL may be formed by a chemical vapor deposition (CVD) process that uses tonen silazene (TOSZ). The second dielectric structure FIL may be formed of a silicon-based dielectric material (e.g., a silicon oxide layer, a silicon nitride layer, or a silicon oxynitride layer).

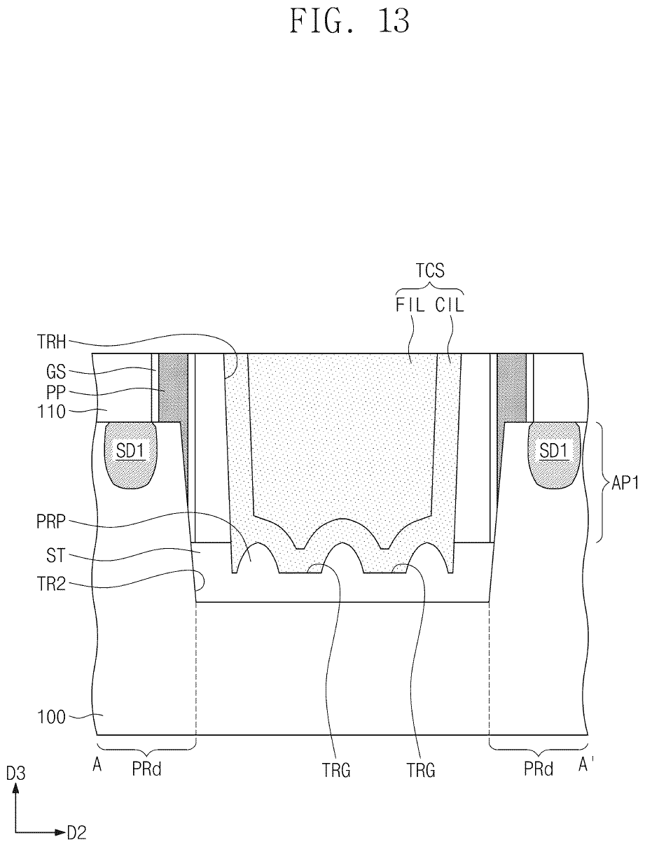

Referring to FIGS. 7 and 13, the first and second dielectric structures CIL and FIL may undergo a planarization process to form a dielectric structure TCS that fills the through hole TRH. The planarization process may continue until top surfaces of the sacrificial patterns PP are exposed. The hardmask patterns MP may all be removed during the planarization process. As a result, the first interlayer dielectric layer 110 may have a top surface coplanar with those of the sacrificial patterns PP, those of the gate spacers GS, and that of the dielectric structure TCS.

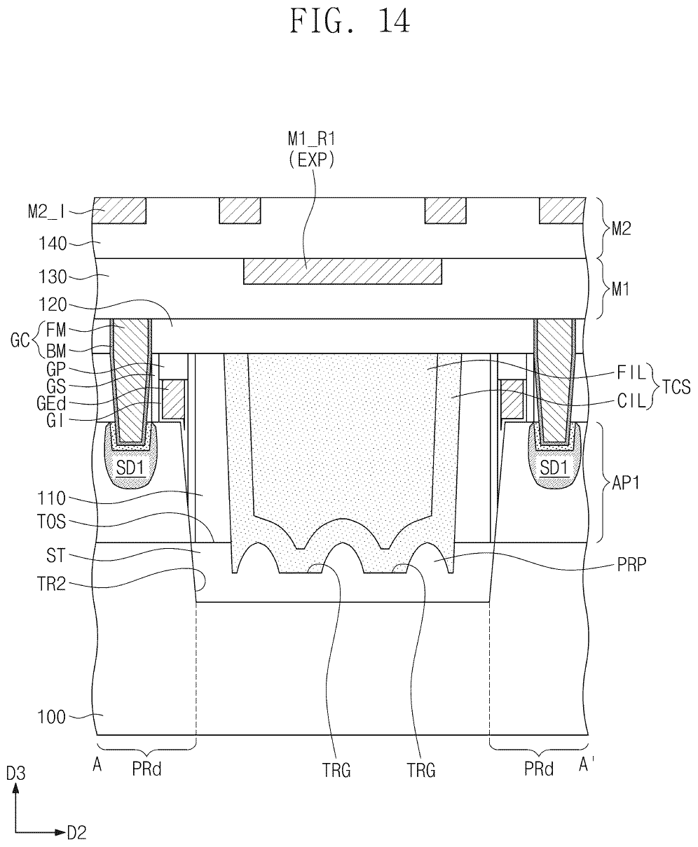

Referring to FIGS. 7 and 14, the sacrificial patterns PP may be replaced with dummy electrodes GEd. For example, the sacrificial patterns PP may be selectively removed. A gate dielectric layer GI may be conformally formed in a region where the sacrificial pattern PP is removed. A gate electrode GE may be formed on the gate dielectric layer GI. The gate electrode GE may be recessed to have a reduced height. A gate capping pattern GP may be formed on the recessed gate electrode GE.

A second interlayer dielectric layer 120 may be formed on the first interlayer dielectric layer 110. The second interlayer dielectric layer 120 may include a silicon oxide layer. Active contacts AC may be formed to penetrate the first and second interlayer dielectric layers 110 and 120 and to have connection with the first and second source/drain pattern SD1 and SD2.

A third interlayer dielectric layer 130 may be formed on the second interlayer dielectric layer 120. A first metal layer M1 may be formed in the third interlayer dielectric layer 130. The first metal layer M1 may include first, second, and third power lines M1_R1, M1_R2, and M1_R3 and first wiring lines M1_I. A fourth interlayer dielectric layer 140 may be formed on the third interlayer dielectric layer 130. A second metal layer M2 may be formed in the fourth interlayer dielectric layer 140. The second metal layer M2 may include second wiring lines M2_I.

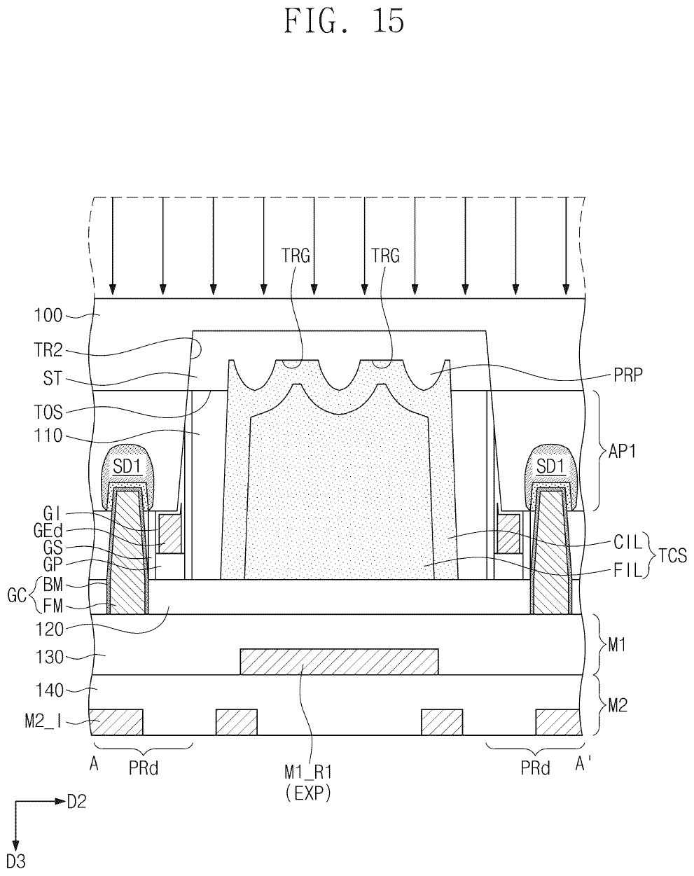

Referring to FIGS. 7 and 15, after a back-end-of-line (BEOL) process is terminated, the substrate 100 may be overturned to expose a bottom surface of the substrate 100. The bottom surface of the substrate 100 may undergo a planarization process to reduce a thickness of the substrate 100.

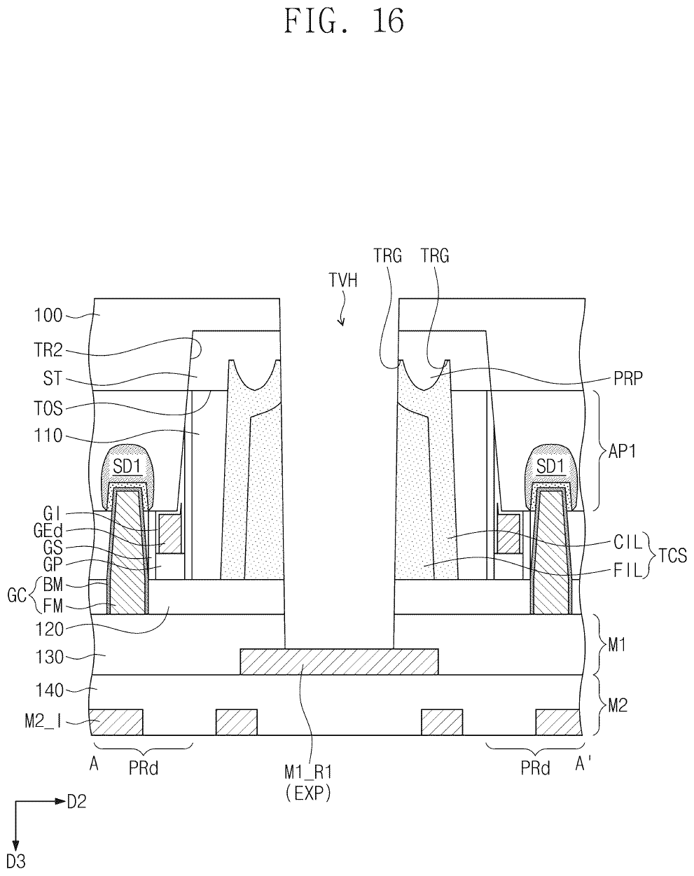

Referring to FIGS. 7 and 16, the bottom surface of the substrate 100 may undergo an anisotropic etching process to form through via holes TVH. The through via holes TVH may sequentially penetrate the substrate 100, the device isolation layer ST, the dielectric structure TCS, and the second and third interlayer dielectric layers 120 and 130, thereby exposing the first power line M1_R1.

According to some embodiments of inventive concepts, the sacrificial pattern PP, the gate spacer GS, and the hardmask pattern MP present on a region where the through via hole TVH will be formed may be replaced with the dielectric structure TCS formed of a silicon-based dielectric material. Thus, the through via hole TVH having a high aspect ratio may be stably formed without process defects.

Referring back to FIGS. 7, 8A, and 8B, a spacer SPC may be formed on an inner sidewall of the through via hole TVH. The through via hole TVH may be filled with metal to form a through via TVI. The through via TVI may be connected to the first power line M1_R1.

A power delivery network layer PDN may be formed on a bottom surface of the substrate 100. The power delivery network layer PDN may be formed to apply a source voltage or a drain voltage to the first, second, and third power lines M1_R1, M1_R2, and M1_R3. The power delivery network layer PDN may include a first lower line LM1 electrically connected to the through via TVI.

The following will describe various embodiments. In the embodiments that follow, a detailed description of technical features repetitive to those discussed above with reference to FIGS. 7, 8A, and 8B will be omitted, and a difference thereof will be discussed in detail.

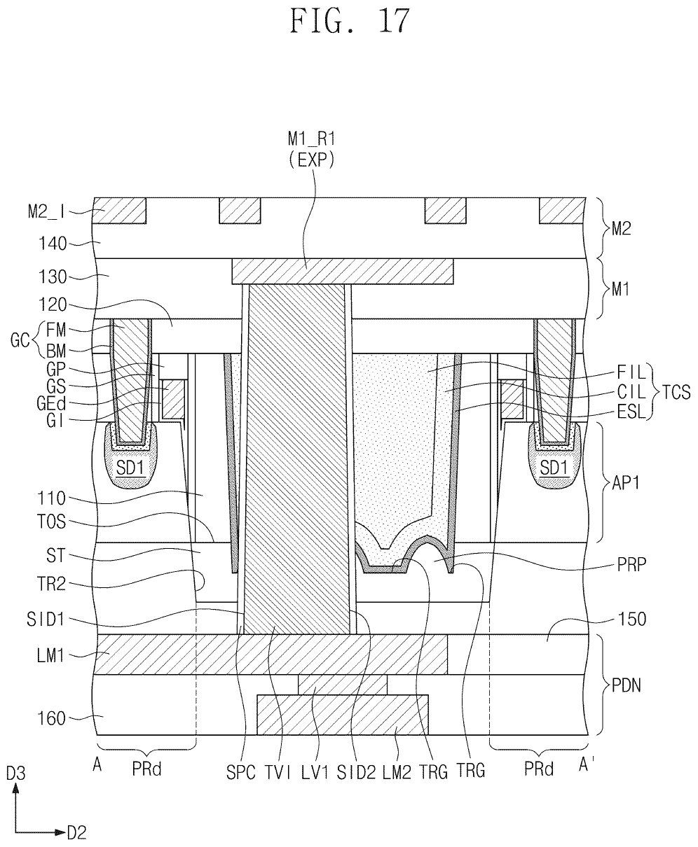

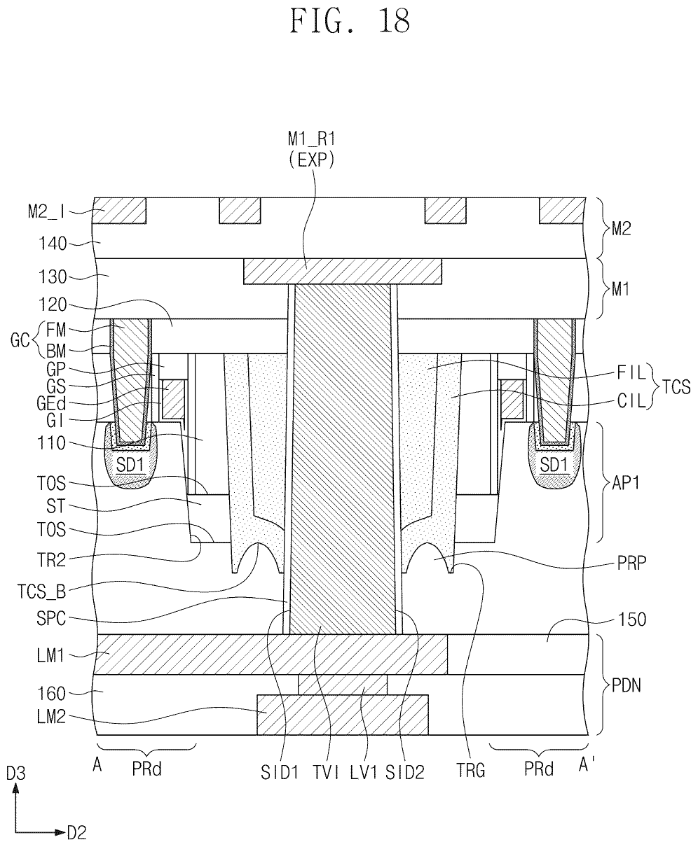

FIGS. 17 and 18 illustrate cross-sectional views taken along line A-A′ of FIG. 7, showing a tap cell according to some embodiments of inventive concepts.

Referring to FIGS. 7 and 17, the dielectric structure TCS may further include an etch stop layer ESL. In an embodiment, the etch stop layer ESL may be provided between the first dielectric structure CIL and the device isolation layer ST and between the first dielectric structure CIL and the first interlayer dielectric layer 110. The etch stop layer ESL may directly cover the trough TRG and the protrusion PRP of the device isolation layer ST. Alternatively, the etch stop layer ESL may be provided between the first dielectric structure CIL and the second dielectric structure FIL.

The etch stop layer ESL may include a material having an etch selectivity with respect to the dielectric structure TCS. For example, the etch stop layer ESL may include at least one selected from SiN, SiCN, SiOC, and SiOCN.

The etch stop layer ESL may be configured to limit and/or prevent a misalignment of the through via TVI. For example, as shown in FIG. 17, even when the through via TVI is misaligned with a center of the first power line M1_R1, the etch stop layer ESL may guide the through via TVI to connect with the first power line M1_R1.

The through via TVI according to inventive concepts may have a first side SID1 adjacent to the etch stop layer ESL. The through via TVI may have a second side SID2 adjacent to the protrusion PRP and the trough TRG. The protrusion PRP of the device isolation layer ST may be adjacent to only the second side SID2 of the through via TVI, and may be omitted on the first side SID1 of the through via TVI.

Referring to FIGS. 7 and 18, the dielectric structure TCS may penetrate the device isolation layer ST to extend into the substrate 100. The dielectric structure TCS may thus have a bottom surface TCS_B in direct contact with the substrate 100. The bottom surface TCS_B of the dielectric structure TCS may be lower than a bottom surface of the device isolation layer ST.

An upper portion of the substrate 100 may include protrusions PRP and a trough TRG between the protrusions PRP. The first dielectric structure CIL may directly cover the trough TRG and the protrusion PRP of the substrate 100. The dielectric structure TCS according to the present embodiment may be formed by an over-etching that occurs in the through hole TRH of FIG. 10. Even though the over-etching occurs to allow the through hole TRH to expose an upper portion of the substrate 100, the dielectric structure TCS may be filled with the dielectric structure TCS to form a through via TVI without process defects.

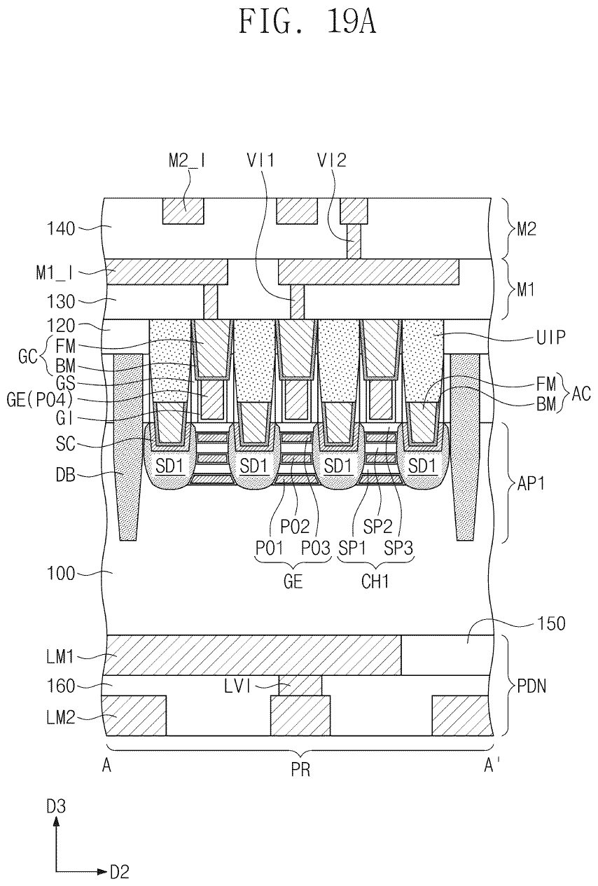

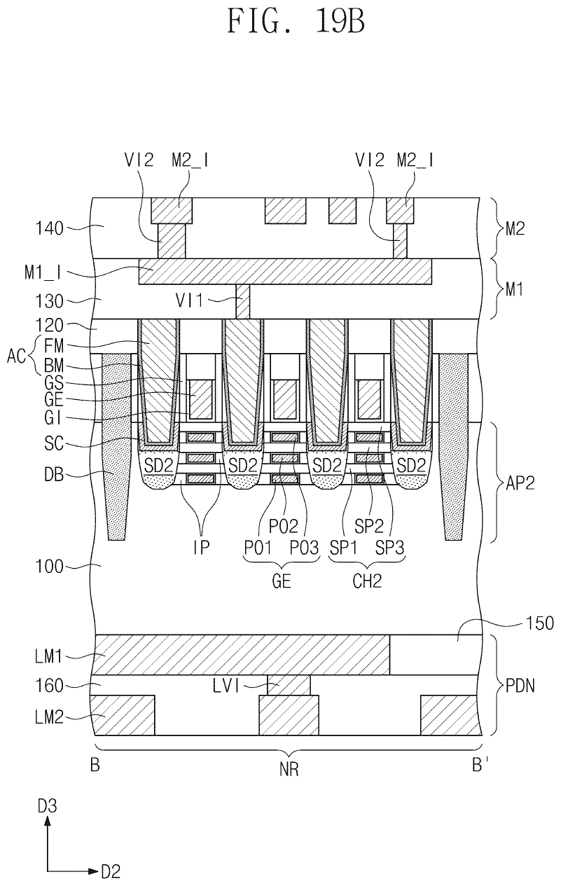

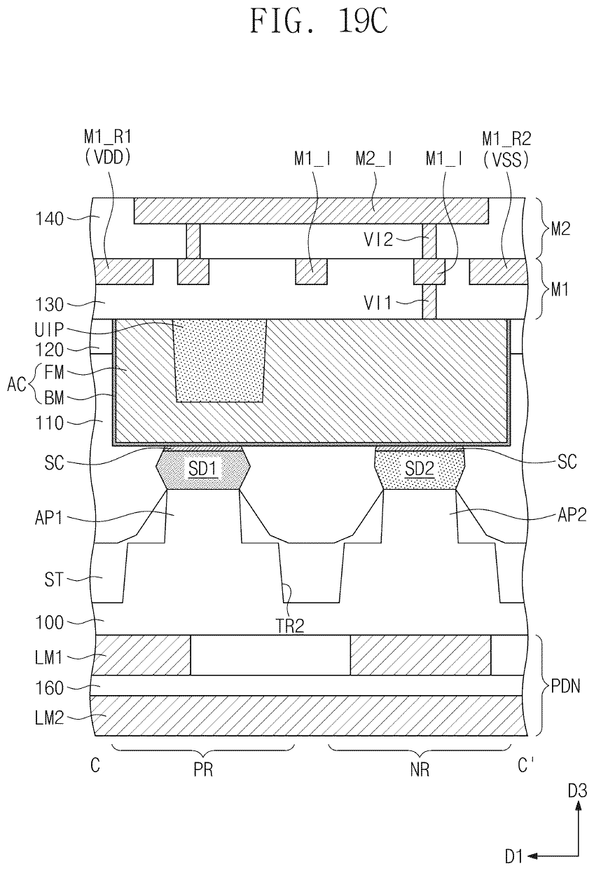

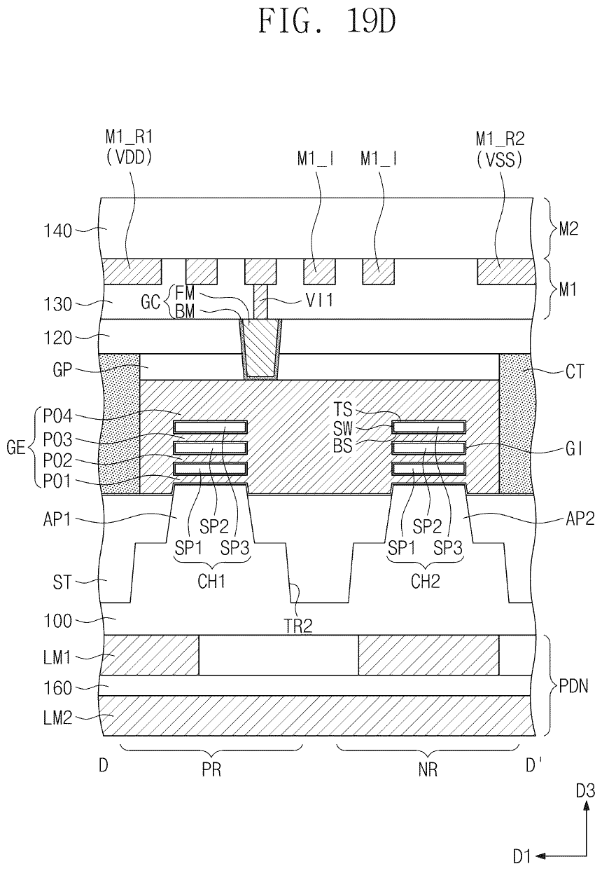

FIGS. 19A, 19B, 19C, and 19D illustrate cross-sectional views respectively taken along lines A-A′, B-B′, C-C′, and D-D′ of FIG. 5, showing a semiconductor device according to some embodiments of inventive concepts.

Referring to FIGS. 5 and 19A to 19D, a first active region PR and a second active region NR may be provided in the first logic cell LC1. A device isolation layer ST may be provided on the substrate 100. The device isolation layer ST may define a first active pattern AP1 and a second active pattern AP2 on an upper portion of the substrate 100. The first active pattern AP1 and the second active pattern AP2 may be respectively provided on the first active region PR and the second active region NR.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon. Each of the first, second, and third semiconductor patterns SP1, SP2, and SP3 may be a nano-sheet.

First source/drain patterns SD1 may be provided on the first active pattern AP1. The first source/drain patterns SD1 may be impurity regions having a first conductivity type (e.g., p-type). The first channel pattern CH1 may be interposed between a pair of first source/drain patterns SD1. For example, the pair of first source/drain patterns SD1 may be connected to each other through the stacked first, second, and third semiconductor patterns SP1, SP2, and SP3.

Second source/drain patterns SD2 may be provided on the second active pattern AP2. The second source/drain patterns SD2 may be impurity regions having a second conductivity type (e.g., n-type). The second channel pattern CH2 may be interposed between a pair of second source/drain patterns SD2. For example, the pair of second source/drain patterns SD2 may be connected to each other through the stacked first, second, and third semiconductor patterns SP1, SP2, and SP3.

Gate electrodes GE may be provided to extend in a first direction D1, while running across the first and second channel patterns CH1 and CH2. The gate electrode GE may vertically overlap the first and second channel patterns CH1 and CH2. A pair of gate spacers GS may be disposed on opposite sidewalls of the gate electrode GE. A gate capping pattern GP may be provided on the gate electrode GE.

The gate electrode GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 19D, the gate electrode GE may be provided on a top surface TS, a bottom surface BS, and opposite sidewalls SW of each of the first, second, and third semiconductor patterns SP1, SP2, and SP3. For example, a transistor according to the present embodiment may be a three-dimensional field effect transistor (e.g., MBCFET or GAAFET) in which the gate electrode GE three-dimensionally surrounds the first and second channel patterns CH1 and CH2.

A gate dielectric layer GI may be interposed between the gate electrode GE and the first channel pattern CH1 and between the gate electrode GE and the second channel pattern CH2. The gate dielectric layer GI may cover the top surface TS, the bottom surface BS, and the opposite sidewalls SW of each of the first, second, and third semiconductor patterns SP1, SP2, and SP3. The gate dielectric layer GI may cover a top surface of the device isolation layer ST below the gate electrode GE.

Inner spacers IP may be provided on the second active region NR. For example, the inner spacers IP may be provided on the second active pattern AP2. The inner spacers IP may be correspondingly interposed between the second source/drain pattern SD2 and the first, second, and third inner electrodes PO1, PO2, and PO3 of the gate electrode GE. The inner spacers IP may be in direct contact with the second source/drain pattern SD2. The inner spacer IP may separate the second source/drain pattern SD2 from each of the first, second, and third inner electrodes PO1, PO2, and PO3 of the gate electrode GE.

Active contacts AC may be provided to penetrate the first and second interlayer dielectric layers 110 and 120 and to have connection with the first and second source/drain patterns SD1 and SD2. A gate contact GC may be provided to penetrate the second interlayer dielectric layer 120 and the gate capping pattern GP and to have connection with the gate electrode GE. A first metal layer M1 may be provided in the third interlayer dielectric layer 130. A second metal layer M2 may be provided in the fourth interlayer dielectric layer 140.

A semiconductor device according to the present embodiment may include the tap cell TC of FIGS. 7, 8A, and 8B, except that the FinFET discussed above is replaced with the GAAFET.

In a semiconductor device according to inventive concepts, as a power delivery network is disposed on a bottom surface of a substrate, it may be possible to increase integration and the degree of freedom of routing in a metal layer. A tap cell of inventive concepts may use a through via to electrically connect the power delivery network to a power line. In the tap cell of embodiments of inventive concepts, a dielectric structure may be formed in advance on a region where the through via will be formed, and thus it may be possible to increase reliability and electrical properties of the through via.

Although inventive concepts have been described in connection with some embodiments of inventive concepts illustrated in the accompanying drawings, it will be understood to those skilled in the art that various changes and modifications may be made without departing from the technical spirit and essential feature of inventive concepts. It will be apparent to those skilled in the art that various substitution, modifications, and changes may be thereto without departing from the scope and spirit of inventive concepts.

What is claimed is:

1. A semiconductor device, comprising:
a substrate including a first dummy region and a second dummy region spaced apart from each other and a trench between the first dummy region and the second dummy region;
a device isolation layer filling the trench between the first dummy region and the second dummy region;
a dielectric structure on the device isolation layer;
an interlayer dielectric layer on the dielectric structure;
a power line on the interlayer dielectric layer;
a power delivery network layer on a bottom surface of the substrate; and
a through via extending from the power delivery network layer through the dielectric structure to the power line, wherein
an upper portion of the device isolation layer includes a protrusion and a trough, and
the dielectric structure covers the protrusion and the trough.

2. The semiconductor device of claim 1, wherein
the dielectric structure includes a first dielectric structure and a second dielectric structure on the first dielectric structure,
the first dielectric structure and the second dielectric structure each include a silicon oxide layer, a silicon nitride layer, or a silicon oxynitride layer.

3. The semiconductor device of claim 1, wherein a height of the trough is lower than a height of a top surface of the device isolation layer.

4. The semiconductor device of claim 1, further comprising:
a plurality of dummy electrodes on the first dummy region and the second dummy region, wherein
a pitch between the plurality of dummy electrodes is a first pitch,
the protrusion includes a plurality of protrusions,
a pitch between the plurality of protrusions is a second pitch, and
the second pitch is equal to the first pitch.

5. The semiconductor device of claim 4, wherein
when viewed in plan, the plurality of protrusions are correspondingly aligned with the plurality of dummy electrodes.

6. The semiconductor device of claim 1, wherein
the power line includes an extension on the dielectric structure,
a width of the extension is greater than a line-width of the power line, and
the through via is connected to the extension.

7. The semiconductor device of claim 6, wherein the extension vertically overlaps the dielectric structure.

8. The semiconductor device of claim 1, further comprising:
an etch stop layer between the dielectric structure and the interlayer dielectric layer,
wherein the etch stop layer includes a material having an etch selectivity with respect to the dielectric structure and the interlayer dielectric layer.

9. The semiconductor device of claim 1, wherein the protrusion is adjacent to at least one side of the through via.

10. The semiconductor device of claim 1, wherein
the through via has a first side and a second side that are opposite to each other,
the protrusion is adjacent to the second side of the through via, and
the protrusion is omitted on the first side of the through via.

11. A semiconductor device, comprising:
a substrate including a first dummy region and a second dummy region spaced apart from each other and a trench between the first dummy region and the second dummy region;
a plurality of dummy electrodes on the first dummy region and the second dummy region, respectively;
a device isolation layer filling the trench between the first dummy region and the second dummy region;
a dielectric structure on the device isolation layer;
an interlayer dielectric layer on the dielectric structure;
a power line on the interlayer dielectric layer;
a power delivery network layer on a bottom surface of the substrate; and
a through via extending from the power delivery network layer through the dielectric structure to the power line, wherein
an upper portion of the device isolation layer includes a plurality of protrusions,
a pitch between the plurality of dummy electrodes is a first pitch,
a pitch between the plurality of protrusions is a second pitch, and
the second pitch is equal to the first pitch.

12. The semiconductor device of claim 11, wherein the dielectric structure covers the plurality of protrusions.

13. The semiconductor device of claim 11, wherein
the through via has a first side and a second side that are opposite to each other,
a first protrusion among the plurality of protrusions is adjacent to the first side of the through via, and
a second protrusion among the plurality of protrusions is adjacent to the second side of the through via.

14. The semiconductor device of claim 11, further comprising:
an etch stop layer between the dielectric structure and the interlayer dielectric layer,
wherein the etch stop layer includes a material having an etch selectivity with respect to the dielectric structure and the interlayer dielectric layer.

15. The semiconductor device of claim 11, wherein
the power line includes an extension on the dielectric structure,
a width of the extension is greater than a line-width of the power line,
the through via is connected to the extension, and
the extension vertically overlaps the dielectric structure.

16. A semiconductor device, comprising:
a logic cell and a tap cell on a substrate,
the substrate including a first active region, a second active region, a first dummy region, and a second dummy region;
a metal layer on the logic cell and the tap cell, the metal layer including a power line; and
a power delivery network layer on a bottom surface of the substrate,
wherein the logic cell includes
a first active region and a second active region,
a gate electrode on the first active region and the second active region,
an active contact adjacent to one side of the gate electrode, and
a gate contact coupled to the gate electrode,
wherein the tap cell includes
a first dummy region and a second dummy region,
a dummy electrode on the first dummy region and the second dummy region,
a dielectric structure between the first dummy region and the second dummy regions, and
a through via that extends from the power delivery network layer through the dielectric structure to the power line,
wherein a bottom surface of the dielectric structure has a wavy profile, and
wherein the tap cell is configured to electrically connect the power delivery network layer and the power line to each other through the through via.

17. The semiconductor device of claim 16, wherein
the substrate further includes a trench between the first dummy region and the second dummy region,
the tap cell further includes a device isolation layer filling the trench between the first dummy region and the second dummy region,
an upper portion of the device isolation layer includes a protrusion and a trough, and
the bottom surface of the dielectric structure covers the protrusion and the trough.

18. The semiconductor device of claim 16, wherein
an upper portion of the substrate below the dielectric structure includes a protrusion and a trough, and
the bottom surface of the dielectric structure covers the protrusion and the trough.

19. The semiconductor device of claim 17, wherein
the dummy electrode is one dummy electrode among a plurality of dummy electrodes on the first dummy region and the second dummy region,
a pitch between the plurality of dummy electrodes is a first pitch,
the protrusion is one protrusion among a plurality of protrusions included in the upper portion of the device isolation layer,
a pitch between the plurality of protrusions is a second pitch, and
the second pitch is equal to the first pitch.

20. The semiconductor device of claim 16, wherein
the power line includes an extension on the dielectric structure,
a width of the extension is greater than a line-width of the power line, and
the through via is connected to the extension.
